(19) United States
(12) Patent Application Publication
(10) Pub. No.: US 2026/0011565 A1
(43) Pub. Date: Jan. 8, 2026

(54) ETCHING METHOD AND PLASMA PROCESSING APPARATUS

(71) Applicant: Tokyo Electron Limited, Tokyo (JP)

(72) Inventors: Akinori KITAMURA, Miyagi (JP); Chungche CHANG, Miyagi (JP); Takahiro TAKEUCHI, Hillsboro, OR (US)

(73) Assignee: Tokyo Electron Limited, Tokyo (JP)

(21) Appl. No.: 19/328,265

(22) Filed: Sep. 15, 2025

Related U.S. Application Data
(63) Continuation of application No. PCT/JP2024/010318, filed on Mar. 15, 2024.

(30) Foreign Application Priority Data
Mar. 27, 2023 (JP) 2023-049812

(51) Int. Cl. H01L 21/308; H01J 37/32; H01L 21/3065

(52) U.S. Cl. CPC H01L 21/3086; H01J 37/32082; H01L 21/3065

(57) ABSTRACT

An etching method includes forming a recess overlapping an opening of a mask by etching a silicon layer, forming a protective layer on at least a side wall of the recess, and etching a bottom of the recess, in which the forming of the protective layer includes forming a precursor layer on at least the side wall of the recess, and modifying the precursor layer into the protective layer, the etching of the bottom of the recess includes supplying a pulse of source radio frequency power from a radio frequency power supply, and supplying a pulse of bias power to a support configured to support the substrate from a bias power supply, and a period during which the forming of the precursor layer is performed does not overlap a period during which the modifying of the precursor layer is performed.

### CROSS-REFERENCE TO RELATED APPLICATIONS

This application is a continuation application of PCT Application No. PCT/JP2024/010318, filed on Mar. 15, 2024, which claims the benefit of priority from Japanese Patent Application No. 2023-049812, filed on Mar. 27, 2023. The entire contents of the above listed PCT and priority applications are incorporated herein by reference.

### BACKGROUND

### Technical Field

Exemplary embodiments of the present disclosure relate to an etching method and a plasma processing apparatus.

### Description of the Related Art

Japanese Unexamined Patent Publication No. 2021-504974 relates to a method and a device for reducing roughness using integrated atomic layer deposition method and etching method. The Japanese Unexamined Patent Publication discloses a technique of depositing a conformal layer on a pattern mask layer of a substrate by an ALD method and then etching a first material layer of the substrate.

### SUMMARY

For example, a mask located on an etching target object may be provided with a pattern (sparse-dense pattern) including openings having a plurality of sizes. In this case, as the trench (groove) provided in the etching target object becomes deeper, the depth of the trench tends to vary (that is, the amount of etching tends to vary). In addition, the smaller the opening through which the trench is provided, the more likely shape abnormalities such as bowing are to occur. Therefore, the present disclosure provides an etching method and a plasma processing apparatus capable of suppressing both the occurrence of the bowing and the variation in the amount of etching depending on the size of the opening.

In one exemplary embodiment, an etching method includes preparing a substrate including a mask having a sparse-dense pattern and a silicon layer located below the mask, forming a recess overlapping an opening of the mask by etching the silicon layer using first plasma generated from a first process gas, forming a protective layer on at least a side wall of the recess, and etching a bottom of the recess using second plasma generated from a second process gas, in which the forming of the protective layer includes forming a precursor layer on at least the side wall of the recess, and modifying the precursor layer into the protective layer using a third process gas, the etching of the bottom of the recess includes supplying a pulse of source radio frequency power from a radio frequency power supply, and supplying a pulse of bias power from a bias power supply to a support configured to support the substrate, and a period during which the pulse of the source radio frequency power is supplied and a period during which the pulse of the bias power is supplied do not overlap each other.

### BRIEF DESCRIPTION OF THE DRAWINGS

FIG. 1 is a diagram for describing a configuration example of a plasma processing system according to an exemplary embodiment.

FIG. 2 is a diagram for describing a configuration example of an inductively coupled plasma processing apparatus according to an exemplary embodiment.

FIG. 3 is a flowchart illustrating an etching method according to an exemplary embodiment.

FIG. 4 is a cross-sectional view of an example of a substrate to which the method in FIG. 3 may be applied.

FIG. 5 is a cross-sectional view illustrating a step of the etching method according to an exemplary embodiment.

FIG. 6 is a cross-sectional view illustrating a step of the etching method according to an exemplary embodiment.

FIG. 7 is a cross-sectional view illustrating a step of the etching method according to an exemplary embodiment.

FIG. 8 is a cross-sectional view illustrating a step of the etching method according to an exemplary embodiment.

FIG. 9 is a cross-sectional view illustrating a step of the etching method according to an exemplary embodiment.

FIG. 10 is a cross-sectional view illustrating a step of the etching method according to an exemplary embodiment.

FIG. 11 is a cross-sectional view illustrating a step of the etching method according to an exemplary embodiment.

### DETAILED DESCRIPTION

Hereinafter, various exemplary embodiments will be described in detail with reference to the drawings. In the drawings, the same or equivalent portions are denoted by the same reference signs.

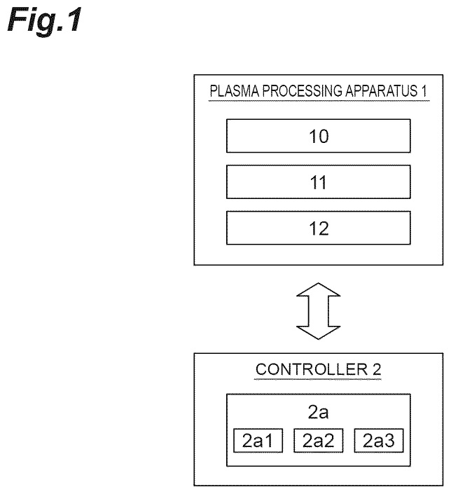

FIG. 1 is a diagram for describing a configuration example of a plasma processing system. In one embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one process gas into the plasma processing space and at least one gas exhaust port for exhausting gases from the plasma processing space. The gas supply port is connected to a gas supply 20 described below and the gas exhaust port is connected to an exhaust system 40 described below. The substrate support 11 is disposed in the plasma processing space and has a substrate support surface for supporting the substrate.

The plasma generator 12 is configured to generate plasma from the at least one process gas supplied into the plasma processing space. The plasma formed in the plasma processing space may be capacitively coupled plasma (CCP), inductively coupled plasma (ICP), electron-cyclotron-resonance (ECR) plasma, helicon wave plasma (HWP), or surface wave plasma (SWP), or the like. In addition, various types of plasma generators including an alternating current (AC) plasma generator and a direct current (DC) plasma generator may be used. In one embodiment, an AC signal (AC power) used in the AC plasma generator has a frequency in a range of 100 kHz to 10 GHz. Therefore, the AC signal includes a radio frequency (RF) signal and a microwave signal. In one embodiment, the RF signal has a frequency in a range of 100 kHz to 150 MHz.

The controller 2 processes computer-executable instructions for causing the plasma processing apparatus 1 to execute various steps described in the present disclosure. The controller 2 may be configured to control each element of the plasma processing apparatus 1 to execute various steps described herein. In one embodiment, the controller 2 may be partially or entirely incorporated into the plasma processing apparatus 1. The controller 2 may include a processor 2a1, a storage 2a2, and a communication interface 2a3. The controller 2 is realized by, for example, a computer 2a. The processor 2al can be configured to read out a program from the storage 2a2 and execute the read out program to perform various control operations. This program may be stored in the storage 2a2 in advance, or may be acquired via the medium when necessary. The acquired program is stored in the storage 2a2, and is read out from the storage 2a2 and executed by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or combinations thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

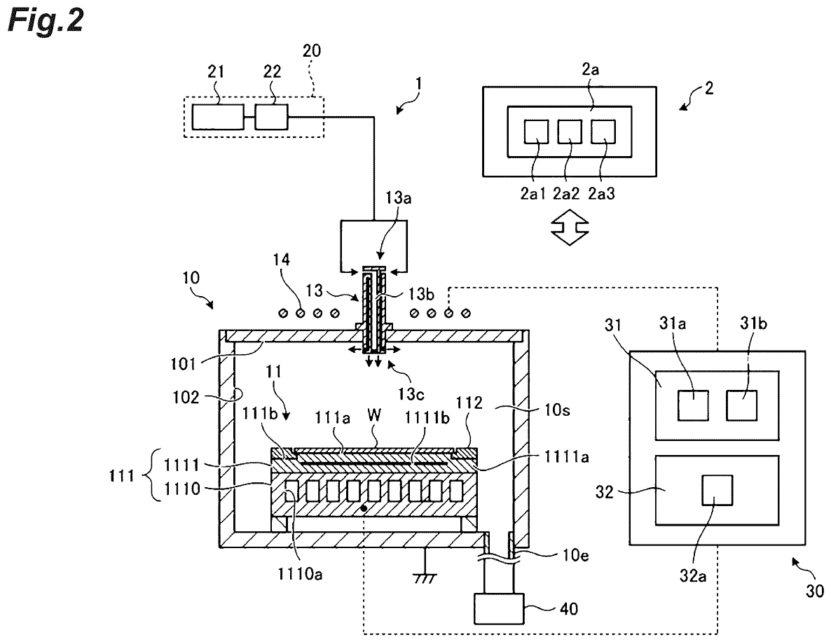

In the following, a configuration example of an inductively coupled plasma processing apparatus, which is an example of the plasma processing apparatus 1, will be described. FIG. 2 is a diagram for describing a configuration example of an inductively coupled plasma processing apparatus.

The inductively coupled plasma processing apparatus 1 includes the plasma processing chamber 10, the gas supply 20, a power supply 30, and an exhaust system 40. The plasma processing chamber 10 includes a dielectric window 101. In addition, the plasma processing apparatus 1 includes a substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s that is defined by the dielectric window 101, a side wall 102 of the plasma processing chamber 10, and the substrate support 11. The plasma processing chamber 10 is grounded.

The substrate support 11 includes a body 111 and a ring assembly 112. The body 111 has a central region 111a for supporting the substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 to surround the substrate W on the central region 111a of the body 111. Thus, the central region 111a is also referred to as a substrate support surface for supporting the substrate W, while the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. In addition, other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32 described below may be disposed in the ceramic member 1111a. In this case, at least one RF/DC electrode functions as the bias electrode. The conductive member of the base 1110 and at least one RF/DC electrode may function as a plurality of bias electrodes. In addition, the electrostatic electrode 1111b may function as the bias electrode. Therefore, the substrate support 11 includes at least one bias electrode.

The ring assembly 112 includes one or a plurality of annular members. In one embodiment, the one or plurality of annular members include one or a plurality of edge rings and at least one cover ring. The edge ring is formed of a conductive material or an insulating material, and the cover ring is formed of an insulating material.

In addition, the substrate support 11 may include a temperature adjusting module that is configured to adjust at least one of the electrostatic chuck 1111, the ring assembly 112, and the substrate to a target temperature. The temperature adjusting module may include a heater, a heat transfer medium, a flow path 1110a, or any combination thereof. A heat transfer fluid, such as brine or gas, flows into the flow path 1110a. In one embodiment, the flow path 1110a is formed in the base 1110, and one or a plurality of heaters are disposed in the ceramic member 1111a of the electrostatic chuck 1111. In addition, the substrate support 11 may further include a heat transfer gas supply configured to supply a heat transfer gas to a gap between a back surface of the substrate W and the central region 111a.

The gas introduction unit is configured to introduce at least one process gas from the gas supply 20 into the plasma processing space 10s. In one embodiment, the gas introduction unit includes a center gas injector (CGI) 13. The center gas injector 13 is disposed above the substrate support 11 and is attached to a central opening formed in the dielectric window 101. The center gas injector 13 has at least one gas supply port 13a, at least one gas flow path 13b, and at least one gas introduction port 13c. The process gas supplied to the gas supply port 13a passes through the gas flow path 13b and is introduced into the plasma processing space 10s from the gas introduction port 13c. The gas introduction unit may include one or a plurality of side gas injectors (SGIs) attached to one or a plurality of openings formed in the side wall 102, in addition to or instead of the center gas injector 13.

The gas supply 20 may include at least one gas source 21 and at least one flow rate control device 22. In one embodiment, the gas supply 20 is configured to supply at least one process gas from the respective corresponding gas source 21 through the respective corresponding flow rate control device 22 to the gas introduction unit. Each flow rate control device 22 may include, for example, a mass flow controller or a pressure-controlled flow rate control device. Further, the gas supply 20 may include at least one flow rate modulation device that modulates or pulses the flow rate of the at least one process gas.

The power supply 30 includes an RF power supply 31, which is coupled to the plasma processing chamber 10 via at least one impedance matching circuit. The RF power supply 31 is a radio frequency power supply configured to supply at least one RF signal (also referred to as RF power or radio frequency power) to at least one bias electrode and the antenna 14. As a result, plasma is formed from at least one process gas supplied to the plasma processing space 10s. Therefore, the RF power supply 31 can function as at least a part of the plasma generator 12. In addition, by supplying the bias RF signal to at least one bias electrode, a bias potential is generated on the substrate W, and ion in the formed plasma can be drawn into the substrate W.

In one embodiment, the RF power supply 31 includes a first RF generator 31a and a second RF generator 31b. The first RF generator 31a is a radio frequency power supply configured to be coupled to the antenna 14 through at least one impedance matching circuit and is configured to generate a source RF signal (also referred to as source RF power or source radio frequency power) for plasma generation. In one embodiment, the source RF signal has a frequency in a range of 0.1 kHz to 150 MHz. In one embodiment, the first RF generator 31a may be configured to generate a plurality of source RF signals having different frequencies. The generated one or plurality of source RF signals are supplied to the antenna 14.

The second RF generator 31b is a bias power supply configured to be coupled to at least one bias electrode via at least one impedance matching circuit and is configured to generate a bias RF signal (also referred to as bias RF power or bias power). The frequency of the bias RF signal may be the same as or different from the frequency of the source RF signal. In one embodiment, the bias RF signal has a frequency lower than the frequency of the source RF signal. In one embodiment, the bias RF signal has a frequency in a range of 0.1 kHz to 60 MHz. In one embodiment, the second RF generator 31b may be configured to generate a plurality of bias RF signals having different frequencies. The generated one or plurality of bias RF signals are supplied to at least one bias electrode. In addition, in various embodiments, at least one of the source RF signal and the bias RF signal may be pulsed. In this case, the first RF generator 31a supplies a pulse of the source radio frequency power to the antenna 14, and the second RF generator 31b supplies a pulse of the bias power to the substrate support 11.

In addition, the power supply 30 may include the DC power supply 32 coupled to the plasma processing chamber 10. The DC power supply 32 includes a bias DC generator 32a. In one embodiment, the bias DC generator 32a is configured to be connected to at least one bias electrode and is configured to generate a bias DC signal. The generated bias DC signal is applied to at least one bias electrode.

In various embodiments, the bias DC signal may be pulsed. In this case, a sequence of the voltage pulses is applied to at least one bias electrode. The voltage pulse may have a pulse waveform of a rectangular, trapezoidal, triangular, or a combination thereof. In one embodiment, a waveform generator for generating the sequence of voltage pulses from the DC signal is connected between the bias DC generator 32a and at least one bias electrode. Therefore, the bias DC generator 32a and the waveform generator constitute a voltage pulse generator. The voltage pulse may have a positive polarity or may have a negative polarity. Further, the sequence of the voltage pulses may include one or a plurality of positive-polarity voltage pulses and one or a plurality of negative-polarity voltage pulses in one cycle. The bias DC generator 32a may be provided in addition to the RF power supply 31, or may be provided instead of the second RF generator 31b.

The antenna 14 includes one or a plurality of coils. In one embodiment, the antenna 14 may include an outer coil and an inner coil disposed coaxially. In this case, each of the RF power supply 31 and the DC power supply 32 may be connected to both the outer coil and the inner coil, or may be connected to either the outer coil or the inner coil. In the former case, the same RF generator may be connected to both the outer coil and the inner coil, or separate RF generators may be separately connected to the outer coil and the inner coil.

The exhaust system 40 may be connected to, for example, a gas exhaust port 10e provided in a bottom of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

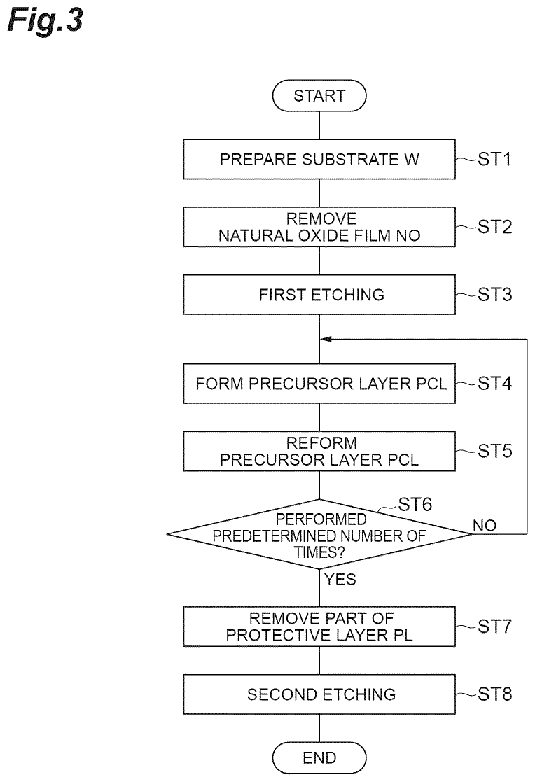

FIG. 3 is a flowchart illustrating an etching method according to an exemplary embodiment. The etching method MT 1 illustrated in FIG. 3 (hereinafter, referred to as “method MT 1”) may be performed by a plasma processing apparatus 1 of the above-described embodiment. The method MT1 may be applied to a substrate W. Therefore, the method MT1 is at least a part of the method for processing the substrate W.

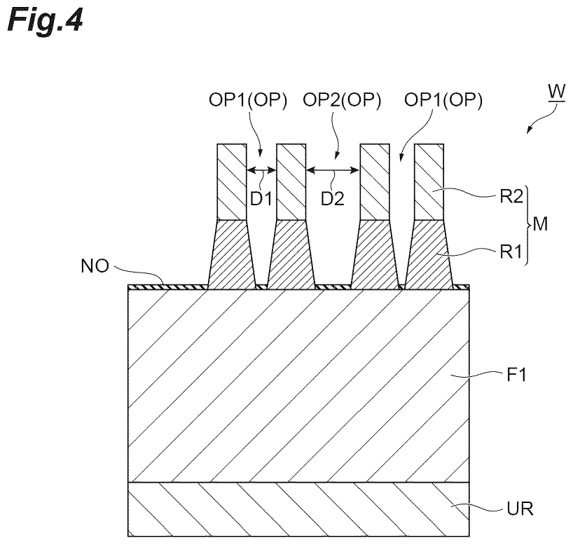

FIG. 4 is a cross-sectional view of an example of a substrate to which the method in FIG. 3 may be applied. As illustrated in FIG. 4, in one embodiment, the substrate W has a mask M, a silicon layer F1 located below the mask M, and an underlying region UR located below the silicon layer F1.

The mask M has at least one opening OP. At least one opening OP may be a hole or a slit. At least one opening OP may be formed by development. The development may be performed by the plasma processing apparatus 1 or may be performed by a developing apparatus different from the plasma processing apparatus 1. The opening OP includes a first opening OP1 and a second opening OP2. A width D1 of the first opening OP1 is smaller than a width D2 of the second opening OP2. Each of the widths D1 and D2 becomes narrower as it approaches the silicon layer F1, but it is not limited to this. The minimum width of the width D1 is, for example, 5 nm or more and 20 nm or less. The minimum width of the width D2 is, for example, 10 nm or more and 30 nm or less. In one embodiment, a portion in which the first opening OP1 is provided may be referred to as a dense pattern, and a portion in which the second opening OP2 is provided may be referred to as a sparse pattern. For this reason, the mask M can also be referred to as a mask having a sparse-dense pattern.

In one embodiment, the mask M has a first region R1 located on the silicon layer F1 and a second region R2 located on the first region R1. The first region R1 contains, for example, an oxide material. The oxide material may be a metal oxide or a silicon oxide (SiO_{X}). x is a positive real number. A thickness of the first region R1 is not particularly limited, but is, for example, 30 nm or more and 100 nm or less. The first region R1 may contain nitrogen or the like. The second region R2 contains, for example, silicon. The silicon may be amorphous silicon or polysilicon. A thickness of the second region R2 is not particularly limited, but is, for example, 30 nm or more and 100 nm or less.

The silicon layer F1 is an etching target in the etching method MT1 and contains silicon. The silicon of the silicon layer F1 may be amorphous silicon, polysilicon, or single crystal silicon. A thickness of the silicon layer F1 is, for example, 200 nm or more and 500 nm or less, but is not limited to this.

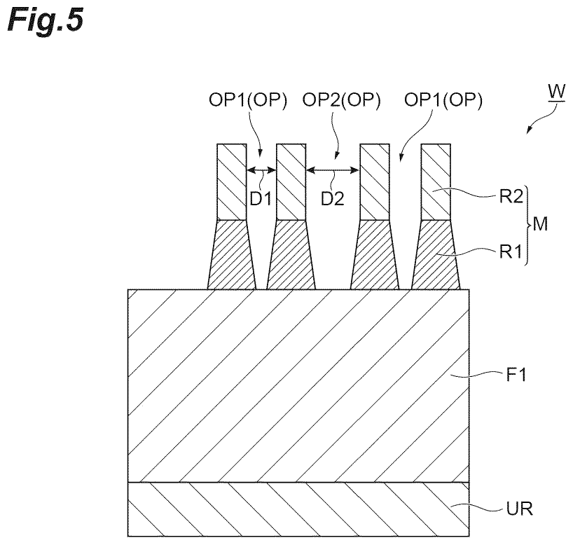

In the following, the method MT1 will be described with reference to FIGS. 5 to 11 in addition to FIG. 4 by using, as an example, the case where the method MT1 is applied to the substrate W by using the plasma processing apparatus 1 in the above-described embodiment. Each of FIGS. 5 to 11 is a cross-sectional view illustrating a step of the etching method according to the exemplary embodiment. In a case where a plasma processing apparatus 1 is used, the method MT1 can be performed in the plasma processing apparatus 1 in a manner that a controller 2 controls each unit of the plasma processing apparatus 1. In the method MT1, as illustrated in FIG. 2, the substrate W on a substrate support 11 disposed in a plasma processing chamber 10 is processed.

As illustrated in FIG. 3, the method MT1 can include Step ST1 to Step ST8. Step ST1 to Step ST8 may be executed in order. Step ST1 to Step ST8 may be performed in the same plasma processing chamber 10.

### (Step ST1)

In Step ST1, the substrate W illustrated in FIG. 4 is prepared. The substrate W may be supported by the substrate support 11 in the plasma processing chamber 10. The opening OP may be formed in Step ST1 or may be formed in advance before Step ST1. A natural oxide film NO can be formed on a surface of the silicon layer F1 in the substrate W. The natural oxide film NO is a surface oxide film of the silicon layer F1, and is formed, for example, during the formation of the opening OP, during the transport of the substrate W into the plasma processing chamber 10, and the like.

### (Step ST2)

In Step ST2, the natural oxide film NO is removed as illustrated in FIG. 5. In Step ST2, for example, the natural oxide film NO is etched using plasma generated from a fluorine-containing gas. The fluorine-containing gas is, for example, a hydrogen fluoride gas (HF gas), a fluorocarbon gas, a hydrofluorocarbon gas, or the like. The fluorocarbon gas is, for example, C₄F₆ gas, C₄F₈ gas, C₃F₈ gas, CF₄ gas, or the like. The hydrofluorocarbon gas is, for example, CHF₃ gas, CH₂F₂ gas, or the like. In one example, first, the fluorine-containing gas is supplied into the plasma processing space 10s from the gas supply 20. Next, the pulse of the source radio frequency power is supplied from the first RF generator 31a to the antenna 14, and the pulse of the bias power is supplied from the second RF generator 31b to the substrate support 11. As a result, electrons accelerated in the plasma processing space 10s collide with the fluorine-containing gas, and plasma is generated from the fluorine-containing gas. Then, the natural oxide film NO is etched using the plasma. The supply of the fluorine-containing gas may be stopped at the end of Step ST2.

### (Step ST3)

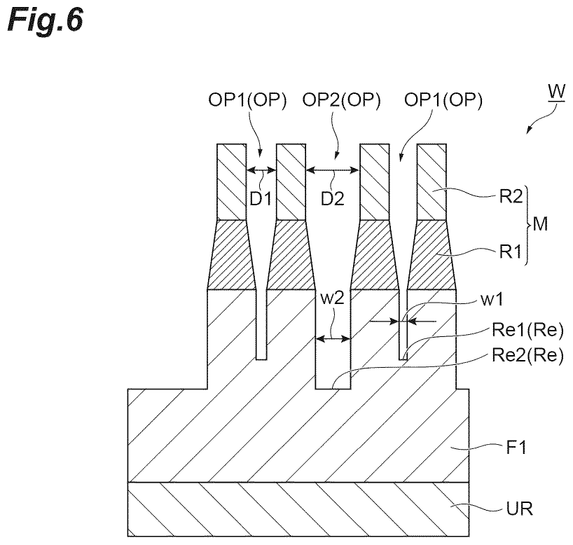

In Step ST3, as illustrated in FIG. 6, a recess Re overlapping the opening OP of the mask M is formed by etching (first etching) the silicon layer F1 using first plasma generated from a process gas (first process gas). In Step ST3, partial etching of the silicon layer F1 is performed. The etching of the silicon layer F1 is anisotropic etching using the mask M, but it is not limited to this. The first process gas may include a halogen-containing gas such as Cl₂. The first process gas may further include an inert gas such as argon gas or nitrogen gas, or may further include an oxygen-containing gas, or the like. The first plasma is, for example, inductively coupled plasma, but it is not limited to this. In one example, first, the first process gas is supplied into the plasma processing space 10s from the gas supply 20. Next, a step of supplying the pulse of the source radio frequency power from the first RF generator 31a to the antenna 14 (first step), and a step of supplying the pulse of the bias power from the second RF generator 31b to the substrate support 11 (second step) are performed. The first plasma is generated by performing the first step and the second step. As a result, electrons accelerated in the plasma processing space 10s collide with the first process gas, and the first plasma is generated from the first process gas. Then, the silicon layer F1 is etched using the first plasma. The supply of the first process gas may be stopped at the end of Step ST3.

In Step ST3, the first step and the second step may not be performed simultaneously. In other words, a period in which the pulse of the source radio frequency power is supplied from the first RF generator 31a to the antenna 14 (first period) and a period in which the pulse of the bias power is supplied from the second RF generator 31b to the substrate support 11 (second period) may not overlap each other. In one example, the first step and the second step are continuously performed in order. In this case, the first period and the second period are continuous with each other. In Step ST3, a length of the first period and a length of the second period may be the same as each other or may be different from each other. In one example, the first period may be 1.5 times or more, 2 times or more, 3 times or less, or 2.5 times or less the second period. The first step and the second step may be performed in order without a gap, but it is not limited to this. For example, a gap time (interval) may exist while switching from the first step to the second step. In other words, a short blank period may exist between the first period and the second period.

In Step ST3, the first step and the second step may be alternately and continuously performed, but it is not limited to this. For example, after the end of the second step, the first step may be performed again at a predetermined interval. In this case, Step ST3 includes a step in which both the pulse of the source radio frequency power and the pulse of the bias power are not supplied (third step). In one example, the first step, the second step, and the third step are continuously performed in order in a certain unit period (one cycle). In other words, the unit period in one example is configured with a first period, a second period, and a period (referred to as a third period or an offset period) in which the third step is performed, the first period and the second period being continuous with each other. The third period may be longer than at least one of the first period and the second period, may be shorter than at least one of the first period and the second period, or may be the same as at least one of the first period and the second period. In one example, the third period is approximately equal to the first period.

The recess Re has a first recess Re1 overlapping the first opening OP1 and a second recess Re2 overlapping the second opening OP2. A width w1 of the first recess Re1 corresponds to the minimum value of the width D1 of the first opening OP1, and a width w2 of the second recess Re2 corresponds to the minimum value of the width D2 of the second opening OP2. Each of a depth of the first recess Re1 and a depth of the second recess Re2 is, for example, 30% or more and 60% or less of the thickness of the silicon layer F1. In one example, the depth of the second recess Re2 is larger than the depth of the first recess Re1 due to a change (microloading effect) in the etching depth depending on the width of the opening OP of the mask M, but it is not limited to this. The depth of the first recess Re1 and the depth of the second recess Re2 may be the same.

### (Step ST4 to Step ST6)

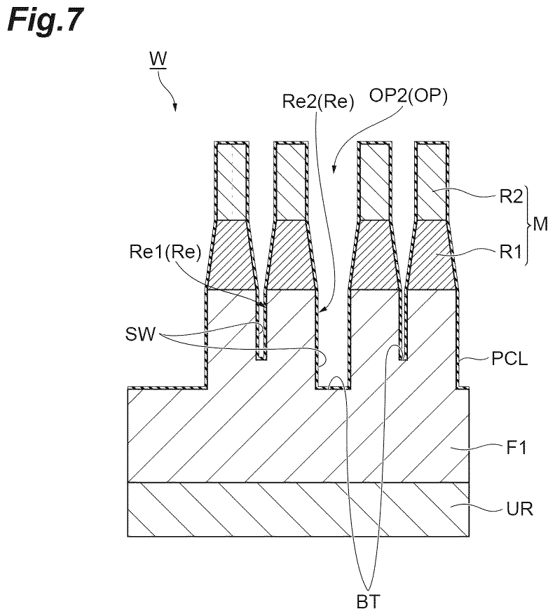

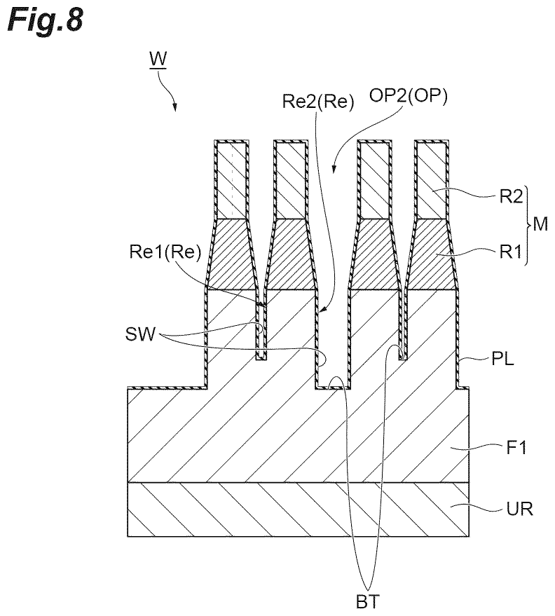

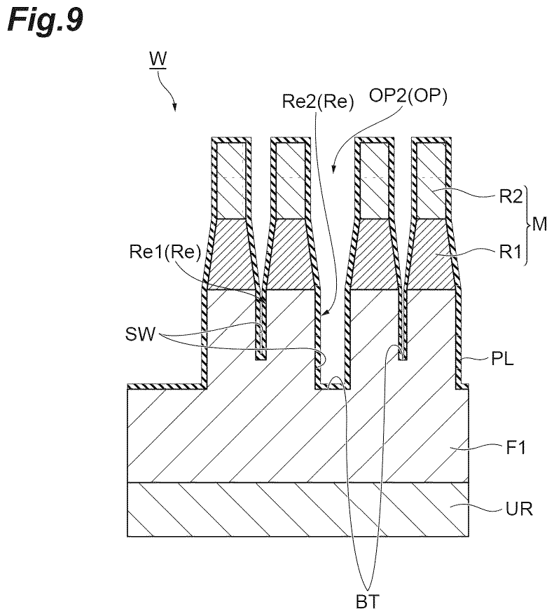

In Step ST4 to Step ST6, as illustrated in FIGS. 8 and 9, a protective layer PL is formed on at least a side wall SW of the recess Re. First, in Step ST4, a precursor layer PCL is formed on at least the side wall SW of the recess Re (layer forming step), as illustrated in FIG. 7. In Step ST4, the precursor layer PCL is formed using plasma generated from the process gas supplied into the plasma processing chamber 10. The precursor layer PCL may cover the entire side wall SW or may cover a part of the side wall SW. The precursor layer PCL may be formed not only on the side wall SW of the recess Re but also on a bottom BT of the recess Re, may be formed on the side surface of the mask M, or may be formed on an upper surface of the mask M. In one example, the precursor layer PCL is formed by a chemical vapor deposition method (CVD method), but it is not limited to this. The CVD method may be a thermal CVD method or a plasma CVD method. By using the CVD method, it is easy to form the precursor layer PCL in a desired region (that is, on the side wall SW of the recess Re). In other words, it is possible to make it difficult to form the precursor layer PCL on the bottom BT of the recess Re (particularly, on the bottom BT of the first recess Re1) as compared with the atomic layer deposition method (ALD method).

The process gas used in Step ST4 may include at least one of a silicon-containing gas such as SiH₄ or SiCl₄, a diluent gas such as argon, helium, or nitrogen, and a halogen-containing gas such as HBr. The silicon-containing gas can correspond to a source gas of the precursor layer PCL. Therefore, the precursor layer PCL is a layer containing silicon as a main component. In a case where the process gas includes the halogen-containing gas, the precursor layer PCL may contain a halogen. For example, in a case where the process gas includes HBr, the precursor layer PCL may contain Br. The supply of the process gas may be stopped at the end of Step ST4.

Next, in Step ST5, the precursor layer PCL is modified into the protective layer PL using an oxygen-containing gas which is a process gas (third process gas) (modifying step) as illustrated in FIG. 8. In Step ST5, the oxygen-containing gas is supplied into the plasma processing space 10s from the gas supply 20. As a result, the precursor layer PCL is oxidized (ashed), and the protective layer PL, which is a silicon oxide film, is formed. The ashing of the precursor layer PCL may be performed simply by supplying the oxygen-containing gas into the plasma processing space 10s, or may be performed using plasma generated from the oxygen-containing gas. The oxygen-containing gas contains, for example, at least one of oxygen, carbon dioxide, carbon monoxide, and carbonyl sulfide.

In a case where Step ST4 and Step ST5 are not performed a predetermined number of times (Step ST6: NO), Step ST4 and Step ST5 are performed again in order. As a result, the precursor layer PCL is deposited on the protective layer PL, and then the precursor layer PCL is ashed. Then, the thickened protective layer PL is formed as illustrated in FIG. 9. In one example, Step ST4 and Step ST5 are alternately repeated until each of Step ST4 and Step ST5 is performed two or more times and ten or less times (for example, three times, five times, seven times, or ten times). In other words, in one example, the cycle of Step ST4 and Step ST5 is performed 2 times to 10 times. In a case where Step ST4 and Step ST5 are performed a predetermined number of times (Step ST6: YES), Step ST7 described later is performed.

### (Step ST7)

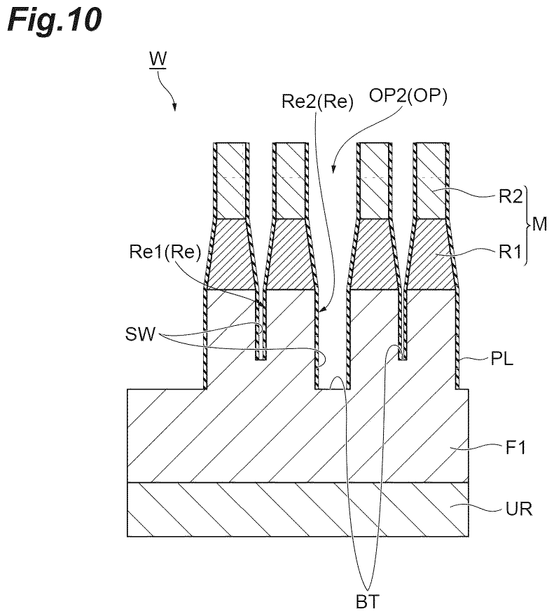

In Step ST7, as illustrated in FIG. 10, a part of the protective layer PL is removed. As a result, the bottom BT of the recess Re can be exposed. In Step ST7, another part of the protective layer PL can be thinned. In Step ST7, for example, a portion of the protective layer PL, which is located on the bottom BT of the recess Re, is removed using the plasma generated from the fluorine-containing gas by the same method as that of Step ST2. The fluorine-containing gas used in Step ST7 is, for example, the same as the fluorine-containing gas used in Step ST2, but is not limited to this. The supply of the fluorine-containing gas may be stopped at the end of Step ST7.

### (Step ST8)

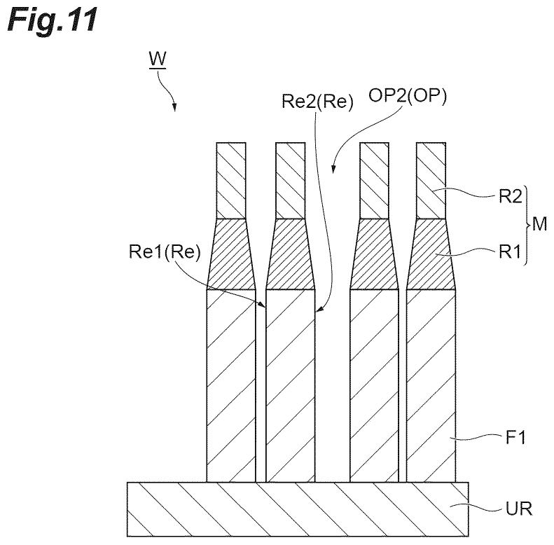

In Step ST8, as illustrated in FIG. 11, the bottom BT of the recess Re is etched (second etching) using second plasma generated from a process gas (second process gas). In Step ST8, the bottom BT of the recess Re is etched by etching the silicon layer F1 using the second plasma. As a result, the bottom BT of the recess Re reaches the underlying region UR or the vicinity of the underlying region UR. The etching of the bottom BT is anisotropic etching using the mask M, but it is not limited to this. In Step ST8, the side wall SW of the recess Re is covered with the protective layer PL. Therefore, an aspect ratio of the etching amount of the bottom BT to the side wall SW can be extremely high. Therefore, not only the bottom BT of the second recess Re2 but also the bottom BT of the first recess Re1 can reach the underlying region UR or the vicinity of the underlying region UR. That is, the microloading effect is less likely to occur. For example, the total etching amount of the first recess Re1 is 96.5% or more, 97% or more, 98% or more, or 99% or more of the total etching amount of the second recess Re2.

The second process gas may be the same as or different from the first process gas. In a case where the second process gas is different from the first process gas, for example, the first process gas includes Cl₂ gas as halogen-containing gas, and the second process gas includes Cl₂ gas and HBr gas as halogen-containing gases. In this case, in the second process gas, the flow rate of the Cl₂ gas is, for example, equal to or greater than 2 times, 3 times, or 4 times the flow rate of the HBr gas, and equal to or less than 5 times the flow rate of the HBr gas. The second process gas may further include an inert gas such as argon gas or nitrogen gas, or may further include an oxygen-containing gas or the like. The second plasma is, for example, inductively coupled plasma, but it is not limited to this.

In one example, first, the second process gas is supplied into the plasma processing space 10s from the gas supply 20. Next, the second plasma is generated by performing the first step and the second step. As a result, electrons accelerated in the plasma processing space 10s collide with the second process gas, and the second plasma is generated from the second process gas. Then, the silicon layer F1 is etched using the second plasma.

The period of the first step in Step ST8 may be the same as or different from the period of the first step in Step ST3. Similarly, the period of the second step in Step ST8 may be the same as or different from the period of the second step in Step ST3. In one example, the period of the first step in Step ST8 is longer than the period of the first step in Step ST3, and the period of the second step in Step ST8 is shorter than the period of the second step in Step ST3. The total period of the first step and the second step in Step ST8 may be the same as or different from the total period of the first step and the second step in Step ST3. In one example, a total period of the first step and the second step in Step ST8 may be longer than a total period of the first step and the second step in Step ST3. In addition, in Step ST8, in addition to the first step and the second step, the third step may be performed similarly to Step ST3. In this case, the period of the third step in Step ST8 may be the same as or different from the period of the third step in Step ST3. The supply of the second process gas may be stopped at the end of Step ST8.

In Step ST3, the controller 2 controls the gas supply 20 and the plasma generator 12 to etch the silicon layer F1 using the first plasma generated from the first process gas, and thereby to form the recess Re in a state where the substrate W is supported by the substrate support 11. In Step ST4 to Step ST6, the controller 2 controls at least one of the gas supply 20 or the plasma generator 12 to form the protective layer PL on at least the side wall SW of the recess Re. In this case, the controller 2 controls the gas supply 20 and the plasma generator 12 such that the precursor layer PCL is modified into the protective layer PL using the third process gas after the precursor layer PCL is formed at least on the side wall SW of the recess Re. In Step ST8, the bottom BT of the recess Re is etched using the second plasma generated from the second process gas. In this case, the controller 2 controls the radio frequency power supply and the bias power supply such that the pulse of the source radio frequency power is supplied in the first period and the pulse of the bias power is supplied to the substrate support 11 in the second period that does not overlap with the first period.

Next, an example of the effects of the exemplary embodiment will be described with reference to the following reference examples. In Reference Example 1, the etching of the silicon layer F1 is performed once. That is, in Reference Example 1, Step ST4 to Step ST8 are not performed. In Reference Example 1, the total etching amount of the first recess Re1 is about 90% of the total etching amount of the second recess Re2. Therefore, in a case where the thickness of the silicon layer F1 is about 200 nm, in Reference Example 1, a difference between the total etching amount of the first recess Re1 and the total etching amount of the second recess Re2 can be 20 nm or more. In Reference Example 2, instead of performing Step ST4 to Step ST7, oxygen ashing is performed between Step ST3 and Step ST8. In Reference Example 2, the total etching amount of the first recesses Re1 is about 95% of the total etching amount of the second recesses Re2. Therefore, in a case where the thickness of the silicon layer F1 is about 200 nm, in Reference Example 2, a difference between the total etching amount of the first recesses Re1 and the total etching amount of the second recesses Re2 can be 10 nm or more.

On the other hand, according to Example 1 in which Step ST1 to Step ST8 of the above-described method MT1 are performed, both the occurrence of the bowing and the variation in the etching amount depending on the size of the opening can be suppressed. Specifically, in Example 1, after partially etching the silicon layer F1 in Step ST3, the protective layer PL is formed on at least the side wall SW of the recess Re in Step ST4 to Step ST6. Then, in Step ST8, the silicon layer F1 is etched again to etch the bottom BT of the recess Re. As a result, not only the bottom BT of the second recess Re2 but also the bottom BT of the first recess Re1 can reach the underlying region UR or the vicinity of the underlying region UR. That is, the microloading effect is less likely to occur. Therefore, in Example 1, the total etching amount of the first recesses Re1 can exceed 99% of the total etching amount of the second recesses Re2. In other words, even in a case where the thickness of the silicon layer F1 is about 200 nm, the difference between the total etching amount of the first recesses Re1 and the total etching amount of the second recesses Re2 can be suppressed to within a few nm. In addition, in Step ST8, since the side wall SW of the recess Re is less likely to be etched due to the protective layer PL, the bowing is less likely to occur in Example 1.

In one embodiment, in Step ST4, the precursor layer PCL may be formed by the CVD method. In this case, the precursor layer PCL can be favorably formed at least on the side wall SW of the recess Re.

In one embodiment, the precursor layer PCL may be formed using a process gas including a silicon-containing gas and a halogen-containing gas.

In one embodiment, in the step of forming the protective layer PL, Step ST4 and Step ST5 may be alternately repeated. In this case, the occurrence of the bowing can be favorably suppressed.

In one embodiment, the method MT1 may include Step ST7 of removing the protective layer PL located on the bottom BT before Step ST8. In this case, the occurrence of the bowing can be favorably suppressed.

Although the various exemplary embodiments have been described above, various additions, omissions, substitutions, and modifications may be made without being limited to the exemplary embodiments described above. In addition, other embodiments can be formed by combining elements in different embodiments.

Here, the various exemplary embodiments included in the present disclosure are described in [E1] to [E10] below.

[E1] An etching method including preparing a substrate including a mask having a sparse-dense pattern and a silicon layer located below the mask, forming a recess overlapping an opening of the mask by etching the silicon layer using first plasma generated from a first process gas, forming a protective layer on at least a side wall of the recess, and etching a bottom of the recess using second plasma generated from a second process gas, in which the forming of the protective layer includes forming a precursor layer on at least the side wall of the recess, and modifying the precursor layer into the protective layer using a third process gas, the etching of the bottom of the recess includes supplying a pulse of source radio frequency power from a radio frequency power supply, and supplying a pulse of bias power from a bias power supply to a support configured to support the substrate, and a period during which the forming of the precursor layer is performed and a period during which the modifying of the precursor layer is performed do not overlap each other.

[E2] The etching method according to [E1], in which in the forming of the precursor layer, the precursor layer is formed by a CVD method.

[E3]

The etching method according to [E1] or [E2], in which the precursor layer is formed using a process gas including a silicon-containing gas and a halogen-containing gas.

[E4] The etching method according to [E1] or [E3], in which in the forming of the protective layer, the forming of the precursor layer and the modifying of the precursor layer are alternately repeated.

[E5] The etching method according to any one of [E1] to [E4], in which the etching of the bottom of the recess includes supplying neither the pulse of the source radio frequency power nor the pulse of the bias power.

[E6] The etching method according to any one of [E1] to [E5], in which each of the first plasma and the second plasma is inductively coupled plasma.

[E7] The etching method according to any one of [E1] to [E6], in which the second process gas is different from the first process gas.

[E8] The etching method according to any one of [E1] to [E7], in which the third process gas is an oxygen-containing gas.

[E9] The etching method according to any one of [E1] to [E8], further including removing the protective layer located on the bottom before the etching of the bottom of the recess.

[E10] A plasma processing apparatus including a chamber, a substrate support provided in the chamber, a gas supply configured to supply a process gas into the chamber, a plasma generator configured to generate plasma from the process gas in the chamber, and a controller, in which the plasma generator includes a radio frequency power supply configured to supply a pulse of a source radio frequency power and a bias power supply configured to supply a pulse of bias power to the substrate support, the controller is configured to, in a state where a substrate including a mask having a sparse-dense pattern and a silicon layer located below the mask is supported by the substrate support, control the gas supply and the plasma generator to form a recess overlapping an opening of the mask by etching the silicon layer using first plasma generated from a first process gas, form a protective layer on at least a side wall of the recess, and etch a bottom of the recess using second plasma generated from a second process gas, in a case where the protective layer is formed, the controller is configured to control the gas supply and the plasma generator such that a precursor layer is formed on at least the side wall of the recess and then the precursor layer is modified into the protective layer using a third process gas, and in a case where the bottom of the recess is etched, the controller is configured to control the radio frequency power supply and the bias power supply such that the pulse of the source radio frequency power is supplied in a first period and the pulse of the bias power is supplied to the substrate support in a second period that does not overlap with the first period.

From the foregoing description, it will be understood that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

### REFERENCE SIGNS LIST

1: plasma processing apparatus
2: controller
10: plasma processing chamber
11: substrate support
12: plasma generator
20: gas supply
F1: silicon layer
M: mask
NO: natural oxide film
OP: opening
OP1: first opening
OP2: second opening
PCL: precursor layer
PL: protective layer
Re: recess
Re1: first recess
Re2: second recess
SW: side wall
W: substrate

What is claimed is:

1. An etching method comprising:
preparing a substrate including:
a mask having a sparse-dense pattern; and
a silicon layer located below the mask;
forming a recess overlapping an opening of the mask by etching the silicon layer using first plasma generated from a first process gas;
forming a protective layer on at least a side wall of the recess; and
etching a bottom of the recess using second plasma generated from a second process gas,
wherein the forming of the protective layer includes:
forming a precursor layer on at least the side wall of the recess; and
modifying the precursor layer into the protective layer using a third process gas,
the etching of the bottom of the recess includes:
supplying a pulse of source radio frequency power from a radio frequency power supply; and
supplying a pulse of bias power from a bias power supply to a support supporting the substrate, and
a period during which the pulse of the source radio frequency power is supplied does not overlap a period during which the pulse of the bias power is supplied.

2. The etching method according to claim 1,
wherein in the forming of the precursor layer, the precursor layer is formed by a chemical vapor deposition (CVD) method.

3. The etching method according to claim 1,
wherein the precursor layer is formed using a process gas including a silicon-containing gas and a halogen-containing gas.

4. The etching method according to claim 1,
wherein in the forming of the protective layer, the forming of the precursor layer and the modifying of the precursor layer are alternately repeated.

5. The etching method according to claim 1,
wherein the etching of the bottom of the recess includes supplying neither the pulse of the source radio frequency power nor the pulse of the bias power.

6. The etching method according to claim 1,
wherein each of the first plasma and the second plasma is inductively coupled plasma.

7. The etching method according to claim 1,
wherein the second process gas is different from the first process gas.

8. The etching method according to claim 1,
wherein the third process gas is an oxygen-containing gas.

9. The etching method according to claim 1, further comprising:
removing the protective layer located on the bottom before the etching of the bottom of the recess.

10. The etching method according to claim 1, wherein the first process gas includes Cl₂ gas, and the second process gas includes Cl₂ gas and HBr gas.

11. The etching method according to claim 1, wherein in the forming of the protective layer, the forming of the precursor layer and the modifying of the precursor layer are alternately repeated two to ten times.

12. The etching method according to claim 1, further comprising removing a natural oxide film on a surface of the silicon layer before forming the recess, wherein the natural oxide film is removed using plasma generated from a fluorine-containing gas.

13. The etching method according to claim 1, wherein a total etching amount of a first recess overlapping a first opening of the mask is 99% or more of a total etching amount of a second recess overlapping a second opening of the mask, the first opening having a smaller width than the second opening.

14. A plasma processing apparatus comprising:
a chamber;
a substrate support in the chamber;
a gas supply configured to supply a process gas into the chamber;
a plasma generator configured to generate plasma from the process gas in the chamber; and
a control circuitry;
wherein the plasma generator includes a radio frequency power supply configured to supply a pulse of a source radio frequency power and a bias power supply configured to supply a pulse of bias power to the substrate support,
the control circuitry is configured to, in a state where a substrate including a mask having a sparse-dense pattern and a silicon layer located below the mask is supported by the substrate support, control the gas supply and the plasma generator to:
form a recess overlapping an opening of the mask by etching the silicon layer using first plasma generated from a first process gas,
form a protective layer on at least a side wall of the recess, and
etch a bottom of the recess using second plasma generated from a second process gas,
in a case where the protective layer is formed, the control circuitry is configured to control the gas supply and the plasma generator such that a precursor layer is formed on at least the side wall of the recess and then the precursor layer is modified into the protective layer using a third process gas, and
in a case where the bottom of the recess is etched, the control circuitry is configured to control the radio frequency power supply and the bias power supply such that the pulse of the source radio frequency power is supplied in a first period and the pulse of the bias power is supplied to the substrate support in a second period that does not overlap with the first period.

15. The plasma processing apparatus according to claim 14, wherein the control circuitry is further configured to control the gas supply and the plasma generator to remove a natural oxide film on a surface of the silicon layer before forming the recess, using plasma generated from a fluorine-containing gas.

16. The plasma processing apparatus according to claim 14, wherein the first process gas includes Cl₂ gas, and the second process gas includes Cl₂ gas and HBr gas.

17. The plasma processing apparatus according to claim 14,
wherein the precursor layer is formed using a process gas including a silicon-containing gas and a halogen-containing gas.

18. The plasma processing apparatus according to claim 14,
wherein in the forming of the protective layer, the forming of the precursor layer and the modifying of the precursor layer are alternately repeated.

19. The plasma processing apparatus according to claim 14,
wherein the etching of the bottom of the recess includes supplying neither the pulse of the source radio frequency power nor the pulse of the bias power.

20. The plasma processing apparatus according to claim 14, further comprising:
removing the protective layer located on the bottom before the etching of the bottom of the recess.
